(19) United States
(12) Patent Application Publication
(10) Pub. No.: US 2018/0106873 A1
(43) Pub. Date: Apr. 19, 2018

(54) METHOD FOR PROVIDING A MAGNETIC SENSOR WITH A BIASING SPIN-ORBIT EFFECTIVE FIELD

(71) Applicant: National University of Singapore, Singapore (SG)

(72) Inventors: Yihong Wu, Singapore (SG); Yanjun Xu, Singapore (SG); Ziyan Luo, Singapore (SG); Yumeng Yang, Singapore (SG)

(21) Appl. No.: 15/788,015

(22) Filed: Oct. 19, 2017

(30) Foreign Application Priority Data
Oct. 19, 2016 (SG) 10201608762Y

(51) Int. Cl. G01R 33/06

(52) U.S. Cl. CPC G01R 33/06

(57) ABSTRACT

The invention relates to magnetic sensor comprising a sensor element that is able to generate a spin-orbit torque (SOT). The SOT acts as a transverse bias field to set a proper working point for the sensor and so ensure that it responds linearly to an external field with maximized sensitivity. It also functions as a longitudinal bias field to suppress domain wall nucleation and propagation. The use of SOT effective field for biasing not only simplifies the sensor structure but also makes it possible to make an ultrathin and semi-transparent magnetic sensor.

### CROSS-REFERENCE TO RELATED APPLICATION

This application claims the benefit of Singapore Patent Application No. 10201608762Y filed Oct. 19, 2016, the contents of which are incorporated herein, in its entirety, by reference.

### FIELD

The current invention relates to a magnetic sensor and to a sensor element for use in a magnetic sensor.

### BACKGROUND

The listing or discussion of an apparently prior-published document in this specification should not necessarily be taken as an acknowledgement that the document is part of the state of the art or is common general knowledge.

Various types of thin film magnetic sensors have been developed in the last two decades for use in the hard disk industry. These include anisotropic magnetoresistance (AMR) sensors, giant magnetoresistance (GMR) sensors, spin-valve (SV) sensors, magnetic tunnel junction (MTJ) sensors, and planar Hall Effect (PHE) sensors. The AMR effect has its origin in spin-orbit coupling (SOC), which results in anisotropic scattering of electrons when they travel through the material. Materials exhibiting a normal AMR effect show a maximum resistivity when the current is parallel to the magnetization direction (ρ_{∥}) and a minimum resistivity when the current is perpendicular to the magnetization direction (ρ_{⊥}). At intermediate angles between the current and magnetization direction, the resistivity of an AMR material is given by ρ(θ)=ρ_{⊥}+(ρ_{∥}−ρ_{⊥})cos² θ, where θ is the angle between the current and the magnetization direction. The immediate application of the AMR effect is in magnetic sensing. When being used in magnetic sensing the magnetization direction is normally set at 45° with respect to the current direction at zero-field so as to maximize the sensitivity. This is apparent from the fact that the first derivative of ρ is maximum when ρ=45°. When used in this configuration the AMR sensor will respond linearly to an external field when the magnitude of the field is small.

To set the magnetization and current angle at 45°, one needs to have a proper transverse bias scheme. There are many different ways to form a transverse bias. The most successful method is the soft adjacent layer (SAL) bias scheme, in which a laminated structure is formed in which a soft ferromagnetic layer is separated from a sensing layer by a thin insulating spacer. The SAL scheme offers several advantages such as providing an adjustable bias field, and having a relatively uniform bias field distribution, and a reduced demagnetizing field. Although it also has drawbacks such as exhibiting a current shunting effect, so far it remains the most successful engineering design. Another commonly used transverse bias technique is the so-called barber pole bias, in which conductive strips are placed on top of the active sensing element and are aligned at 45° to the easy axis of the sensing element. In this way, the current flow direction in the active layer will be aligned at 45° to the magnetization direction. A primary drawback of barber pole bias is that only a small portion of the sensing element is active. Moreover, the process for forming such kind of structure is complex, thereby increasing the overall cost of the sensor.

In actual sensors, in addition to the transverse bias, one also needs a longitudinal bias to stabilize the domain structure in order to reduce Barkhausen noise caused by domain wall motion.

So far, the most widely studied longitudinal bias scheme is the contiguous (or abutted) junction scheme. This scheme uses permanent magnets positioned to either side of the active element, and abutting the active element, to control bias. There are a number of factors involved in forming a proper bias in this scheme, but key among them is selection of a proper material with an appropriate thickness, and the control of the junction shape between the permanent magnet and the active element of the sensor.

One significant drawback of this scheme is that the bias field usually is not uniform across the longitudinal direction of the sensor. It is normally stronger at the two edges and weaker at the center. If the center portion is properly biased, then it is unavoidable that the edge regions will be over-biased, leading to the formation of so-called dead regions. These inactive regions will generally degrade the sensitivity of the sensor. The influence of the dead region becomes more prominent when the sensor width becomes smaller.

An alternative scheme which can suppress the effect of the inactive region is the so-called lead overlaid structure. In this scheme the contact electrodes are extended over the abutted junction and thus form a direct electrical contact with the inactive region of the sensor. However, comparative studies of magnetic noise in sensors with a contiguous junction and lead overlaid design showed that magnetic noise is twice as large as Johnson noise for a lead overlaid design, while it is comparable with Johnson noise for the contiguous junction design. The higher magnetic noise is attributed to a weaker longitudinal bias field with the lead overlaid design. Although the uniformity of bias can be improved by other bias techniques such as exchange bias from an antiferromagnet, this generally leads to a degradation of sensor sensitivity.

Proper biasing schemes are also required for SV and MTJ sensors. A typical spin-valve in its simplest form consists of two ferromagnetic (FM) layers separated by a non-magnetic spacer and an antiferromagnetic (AFM) layer in contact with one of the ferromagnetic layers. The thickness of the spacer is chosen such that there is little exchange coupling between the two FM layers. The magnetization of the FM layer which is in direct contact with the AFM layer is “pinned” by the latter, thus this FM layer is commonly called a pinned layer. The magnetization of the other FM layer is free to rotate to respond to an external field, thus it is called a free layer. A typical material for the FM layer is NiFe or CoFe, while the spacer is generally made of copper (Cu). A thin layer of Co or CoFe with high Co composition is often added at the FM and Cu interface to increase the MR ratio due to the high polarization ratio of the Co or CoFe material and reduced inter-diffusion at the interface with Cu. The choice of AFM is an issue of high complexity. The exchange bias between AFM and FM sets the direction between the magnetization of the free and pinned layers at 90° at zero-field. This is to ensure that the sensor will respond linearly to an external field. When being used as a sensor, a constant current is applied to the sensor, and the voltage change caused by the external field is detected as the sensing signal.

A MTJ sensor typically has the same structure as that of SV sensors. The main difference is that in the case of MTJ, the non-magnetic layer is replaced by an insulator such as AlOₓ or MgO. In addition, instead of current flowing in the plane, current flows vertically to the film plane.

Various longitudinal bias schemes have been developed for both SV and MTJ sensors. This purpose is to obtain a good linearity with less asymmetry and at the same time suppresses Barkhausen noise. The former is achieved though setting the magnetization of the free layer at 90° to that of the pinned layer, parallel to the external field direction. This can be achieved through first inducing an easy axis in an appropriate direction during deposition of the free layer and then using shape anisotropy to stabilize it in the same direction. However, the shape anisotropy alone becomes insufficient as the aspect ratio of the sensor decreases. The following additional magnetic fields need to be taken into account when designing the sensor:

(i) fringe field from the pinned layer;

(ii) various coupling fields from the pinned layer including the so-called interlayer coupling field; and

(iii) current-induced field from highly conductive layers such as the spacer layer. Ideally all the external fields other than the signal field should be reduced to zero so as to obtain a high sensitivity, good linearity and null asymmetry for the read sensor. However, this also means that the sensor is too susceptible to external disturbances. External disturbances induce noise or baseline popping and shift in the readout signal, in particular, the domain-formation and movement-induced Barkhausen noise. The latter is an issue of high complexity because it depends on many factors such as the material and shape of the free layer, the process used to form it and the effect of other layers. Therefore, as in the case of AMR sensors, a longitudinal bias of an appropriate strength is normally used to suppress multidomain formation in the free layer of spin-valve and MTJ sensors. Most of the longitudinal biasing techniques for spin-valve sensors are based on the earlier work on AMR sensors, and may be divided into two groups. The first group is based on exchange bias between a ferromagnet and an antiferromagnet and the second group is based on the magnetostatic interaction or exchange coupling between a ferromagnetic soft film and a permanent or hard magnet.

All of these biasing schemes significantly increase the number of process steps necessary in the manufacture of a sensor. Moreover, the mostly commonly used biasing scheme, patterned longitudinal bias, often results in non-uniform bias field in the sensor area.

There remains a need for a magnetic sensor which achieves high linearity while being relatively simple to manufacture.

### SUMMARY OF THE DISCLOSURE

According to a first aspect there is provided a magnetic sensor which uses the so-called spin-orbit torque (SOT) effect. The magnetic sensor comprises a sensor element with an easy axis and a hard axis which is able to generate a spin-orbit torque (SOT) when a charge current flows through it. In order to put the sensor into practical effect it further comprises electrodes disposed along the easy axis to carry a sense current and the same current is also used to generate SOT for transverse bias.

When SOT is generated, there are two types of effective fields. The so-called field-like effective field is in the plane of the sensor element, and perpendicular to the current direction. The so-called damping-like effective field is out-of-plane. It has now been found that the field-like effective field can act as a transverse bias field to set a proper working point for the sensor and so ensure that it responds linearly to an external field with maximized sensitivity. It can also function as a longitudinal bias field to suppress domain wall nucleation and propagation. In an embodiment the magnet sensor further comprises electrodes disposed along the hard axis to provide a longitudinal bias.

Accordingly, structures used in conventional magnetic sensors to provide transverse bias control, such as a SAL or barber pole, or to provide longitudinal bias control, such a contiguous junction arrangement using a permanent magnet, can be avoided.

According to a second aspect there is provided a magnetic sensor consisting essentially of a sensor element which is able to generate a spin-orbit torque (SOT) when charge current is passing through it.

According to a third aspect there is provided an ultrathin and semitransparent magnetic sensor. The use of spin-orbit torque effective field for transverse biasing allows a reduction in the total thickness of the sensors down to 3-4 nm, thereby leading to the semitransparency. Despite the extremely simple design, a spin-orbit torque effective field biased sensor exhibits level of linearity and sensitivity comparable to those of sensors using more complex linearization schemes.

According to a fourth aspect there is provided a method of measuring a change in a magnetic field, comprising using a sensor element as described herein both to provide transverse bias and, optionally, longitudinal bias and sense the change in the magnetic field.

### BRIEF DESCRIPTION OF THE DRAWINGS

In order that the disclosure may be readily understood and put into practical effect, reference will now be made to the accompanying figures. The figures together with the description serve to further illustrate the embodiments of the invention and explain various principles and advantages.

FIG. 1. (a) Schematic drawing of a conventional PHE sensor. (b) Schematic drawing of a SOT-biased sensor in accordance with the current invention employing a bilayer. (c) Schematic drawing of a SOT-biased sensor in accordance with the current invention employing a multilayer.

FIG. 2. (a) Schematic drawing of a SOT-biased PHE sensor in accordance with the current invention. (b) Section through the PHE sensor of (a) showing the structure of the sensor element.

FIG. 3. Plot showing the PHE signal of a sensor with a structure of SiO₂/[Pt(0.4)/FeMn(0.6)]₆/Pt(1) measured at different sensing currents.

FIG. 4. (a) Schematic of AMR sensor with soft adjacent layer biasing. (b) Schematic of AMR sensor with barber pole biasing. (c) Schematic of SMR/AMR sensor with SOT-biasing in accordance with the current invention. (d) Illustration of SOT generation mechanism.

FIG. 5. (a) Simulated transmittance in the visible range for NiFe(1.5)/HM(2) bilayers on quartz substrate with different HM: Pt (solid-line), Ta (dashed-line) and W (dotted-line). (b) Simulated oxide thickness dependence of transmittance at λ=500 nm for Pt(2)/NiFe(1.5)/oxide(d_{oxide}) trilayers with different oxides: Ta₂O₅ (dashed-dotted-line), SiO₂ (dotted-line), MgO (solid-line), Al₂O₃ (short-dashed-line) and bilayer without oxide (dashed-line). (c) Measured transmittance for NiFe(1.5)/Pt(d_{Pt}) with d_{Pt}=1.5 nm (dashed-dotted-line), 2 nm (solid-line) and 2.5 nm (dotted-line) and the bare substrate (dashed-line). (d) Measured M-H loops for NiFe(d_{NiFe})/Pt(2) films with d_{NiFe}=1.7 nm, 1.8 nm, 1.9 nm and 2 nm. Insets in (a) and (b) are the schematics of NiFe/HM bilayer and Pt/NiFe/Oxide trilayer; respectively, and inset in (c) is a photograph of NUS logo covered by the coupon film of NiFe(1.8)/HM(2).

FIG. 6. Differential AMR sensors with SOT biasing. (a) Schematic of a differential AMR sensor with two SOT-biased sensor elements and each sensor element consists of a HM/FM bilayer. (b) Calculated AMR curves for both sensors (left panel: sensor 1 and right panel: sensor 2) at different bias fields: −0.2 Oe to −2.66 Oe for sensor 1 and 0.2 Oe to 2.66 Oe for sensor 2. At these H_{FL} values, θ=−7.5° to −75° for sensor 1 and θ=7.5° to 75° for sensor 2. (c) Calculated magnetoresistance as a function of external field H_{y} with H_{FL}=±2.66, ±1.72, ±1.23, ±0.82, and ±0.41 Oe, respectively. The calculation uses Hₖ=1.4 Oe and Hₑ=0.5 Oe (in the same direction of Hₖ) in the calculation.

FIG. 7. H_{FL} extracted by second order PHE method. (a) Experimentally determined H_{FL} as a function of j_{Pt} for NiFe(t_{NiFe})/Pt(2) bilayers with t_{NiFe}=1.8, 2, 3 and 4 nm, using 2^{nd} order PHE measurement. (b) Extracted H_{FL}/j_{Pt} ratio as a function of t_{NiFe} for NiFe(t_{NiFe})/Pt(2) (square symbol) and calculated Oersted field (H_{Oe}) at the center of NiFe layer (dotted-line). Solid-line is the fitting using eq. 3 assuming θ_{SH}=0.15 and α=0.122.

FIG. 8. (a) Scanning electron micrograph and schematic of AMR bridge sensor. Scale bar: 1 mm. (b) Measured MR curves of both sensors (left panel: sensor 1 and right panel: sensor 2) at different bias current densities: 1.9×10⁵-1.9×10⁶ A/cm². c) Output signals as a function of H_{y} at different bias current densities.

FIG. 9. SOT biased Wheatstone AMR bridge sensor based on NiFe(1.8)/Pt(2) bilayer structure. (a) SEM image and schematic of the AMR bridge sensor. Scale bar 500 μm. (b) Measured AMR curves of all the four sensor elements at the same bias current densities of 3.67×10⁵ A/cm². (c) Output signals as a function of H_{y} at different bias current densities. (d) AMR response of the bridge sensor to an AC magnetic field with a frequency of 0.1 Hz but with a varying amplitude: 10 nT, 500 nT, 2 pT, 10 pT and 30 pT. The AC field is in the hard axis direction. The sensor is biased at jₚ=3.67×10⁵ A/cm². (e) Output signals extracted from (d) with different amplitude: 30 μT, 500 nT and 10 nT. (f) Fourier transform of the waveforms in (e).

FIG. 10. Dependence of (a) power consumption (b) sensitivity and (c) dynamic range on the long axis length a (symbols: experiment; solid curve: simulation).

FIG. 11. Linearity error versus dynamic range for NiFe(1.8)/Pt(2) ellipsoidal sensors with a=800, 400 and 200 μm, respectively.

FIG. 12. On-chip current detection by SOT-biased AMR sensor based on NiFe(1.8)/Pt(2) bilayer structure. (a) Schematic of the device for on-chip current detection; (b) Schematic cross-section of the device in (a); (c) Output signals as a function of current in the on-chip copper wire at different j_{Pt}; (d) Calculated Oersted field (H_{y}) at the sensor plane as a function of current density in the Cu wire (inset: distribution of y-component of the Oersted field in yz plane at I_{Cu}=1×10⁵ A/cm²); (e) Output waveforms corresponding to AC current with varying amplitude: 100 mA, 2 mA and 100 μA, but a fixed frequency of 0.1 Hz. The sensor is biased at j_{Pt}=1.1×10⁶ A/cm²; (f) Fourier transform of the waveforms in (e).

### DESCRIPTION

A magnetic sensor which uses the SOT effect is disclosed herein.

In the last few years, extensive efforts have been devoted to the study of SOT and the application of it to manipulate magnetization of ferromagnetic materials with either bulk or structure inversion asymmetry. SOT occurs in a variety of ferromagnet (FM)/heavy metal (HM) heterostructures including Pt/Co/AlOₓ, in which it was first observed. A charge current passing through a ferromagnet (FM), a heavy metal (HM) layer or a ferromagnet heterostructure generates a non-equilibrium spin density through the inverse spin galvanic effect (ISGE). The ISGE, in turn, exerts a torque on the local magnetization of the FM through either s-d (in the case of a transition metal) or p-d (in the case of a dilute magnetic semiconductor) exchange coupling. As the ISGE originates from spin-orbit coupling, the resultant torque is referred to as spin-orbit torque (SOT). Unlike spin transfer torque, which requires non-collinear magnetic configurations such as in magnetic/non-magnetic multilayers and domain walls, the SOT can be realized in structures with a uniform magnetization.

Although spin-orbit coupling induced spin polarization of electrons has been studied extensively in semiconductors, investigations of spin-orbit induced non-equilibrium spin density in ferromagnets and the effect of the resultant SOT on local magnetization have not. The first experimental observation of SOT was in Ga_{0.94}Mn_{0.06}As dilute magnetic semiconductor (DMS) with a Curie temperature of 80 K. The Ga₁₋ₓMnₓAs layer grown epitaxially on GaAs (001) substrate is compressively strained, which results in a Dresselhaus-type spin-orbit interaction that is linear in momentum. When a charge current was passed through the DMS layer below its Curie temperature, the resultant SOT was able to switch the magnetization with the assistance of an external field and crystalline anisotropy. The lack of bulk inversion asymmetry (BIA) in transition metal FM has prompted investigation of the SOT effect in FM heterostructures with structure inversion asymmetry (SIA).

The first observation of a current-induced SOT was in a thin Co layer sandwiched by a Pt and an AlOₓ layer. Due to the asymmetric interfaces with Pt and AlOₓ, electrons in the Co layer experience a large Rashba effect, leading to sizable current-induced SOT. The Pt layer is necessary because otherwise the Rashba effect due to SIA alone would be too weak to cause any observable effect in the Co layer. The presence of Pt also gives rise to a complex scenario concerning SOT in HM/FM bilayers because, in addition to the Rashba SOT, spin current diffuses from the Pt layer due to spin Hall Effect (SHE) and exerts a torque on the FM layer because it transfers the spin angular momentum to the local magnetization. To differentiate it from the Rashba SOT, it is also called SHE-SOT. To date, the SOT effect has been observed in several HM/FM bilayers with different FMs such as CoFeB, Fe, NiFe and HMs such as Pt, Ta, and W. An average effective field strength of 4×10⁻⁶ Oe/(A/cm²) has been obtained. However, SOT has never been utilised in a magnetic sensor, nor suggested for any such use.

A magnetic sensor of this invention comprises a sensor element with an easy axis and a hard axis which is able to generate a spin-orbit torque (SOT) when a current is passing through it. In order to put the sensor into practical effect it further comprises electrodes disposed along the easy axis to carry a sense current and the same current is also employed to generate SOT effective field for transverse bias.

In an embodiment the field-like effective field can act as a transverse bias field to set a proper working point for the sensor and so ensure that it responds linearly to the external field with maximized sensitivity.

Although the SOT effective field is used for transverse basing, it also promotes the formation of large domains, thereby suppressing the domain motion which is the origin of Barkhausen noise. Therefore, in an embodiment, the sensor can have 4 electrodes, two along the magnetic easy axis (i.e., long axis of the sensing element), and the other two along the hard or short axis direction. Current supplied by the two electrodes in the easy axis direction serve as both a transverse bias and sense current, whereas the electrode pair in the hard axis direction can be used to generate a longitudinal bias (if needed). A longitudinal bias is not necessary to be turned on all the time; it is only needed when multiple domains are formed.

In an embodiment the sensor element is made by a material with the capability of generating an SOT when a charge current passes through it, and thereby to generate an appropriate bias field. The person skilled in the art will appreciate a charge current passing through a ferromagnet (FM), a heavy metal (HM) layer or a ferromagnet heterostructure generates a non-equilibrium spin density through the inverse spin galvanic effect (ISGE) and will be able to select structures in which SOT may be generated. Materials that exhibit a SOT effect include Pt/Co/AlOₓ and HM/FM bilayers with different FMs such as CoFeB, Fe, NiFe and HMs such as Pt, Ta, and W. Other materials that are able to generate the SOT effective field can also be used as the sensor element, such as HM/antiferromagnet (AFM) bilayers, HM/AFM multilayers, FM/topological insulator (TI) bilayers, magnetic TI, dilute magnetic semiconductors, FM/transition metal dichalcogenide (TMD) heterostructures, FM/Weyl metal or semimetals.

The sensor element may be in the form of a single layer of material, a heterostructure, or multilayers. These materials can be in the form of a single layer with bulk inversion asymmetry or multilayers with structural inversion asymmetry. The latter can be layered structures of two or more types of materials with at least one the materials being a heavy metal (HM) with strong spin-orbit (SO) coupling, and the remaining materials being either an antiferromagnet (AFM) or a ferromagnet (FM). The layered structure can be a heterostructure consisting of an FM (or AFM) and a HM or multilayers consisting of ultrathin FM (or AFM) and HM layers. In the latter case, the HM layer is preferably at the Stoner limit so as to be magnetized easily when in contact with the AFM or FM by the magnetic proximity effect. With appropriate structural optimization, the HM/AFM (or FM) layer exhibits ferromagnetic properties above room temperature whereby magnetization can be rotated or switched by its own current without the need for any additional external field. The muitilayers can be configured to function as an active layer for various types of magnetic sensing devices.

In an embodiment the sensor element may comprise multilayers of HM with an AFM layer made from a material selected from one or more of the group consisting of FeMn, IrMn, NiFe, PtMn, NiMn, PtNiMn, Mn, Cr, NiO, CoO and CuMnAs.

In an embodiment the sensor element may comprise a FM material selected from one or more of the group consisting of Co, Fe, Ni, CoFeB and Gd, and alloys comprising Co, Fe, Ni, CoFeB or Gd.

In an embodiment the sensor element may comprise a HM material selected from one or more of the group consisting of Pt, Pd, Ta, W, Pb, Nb, topological insulators, transition metal dichalcogenide (TMD) and Weyl metal or semimetals.

In an embodiment the sensor element may comprise a material selected from the group consisting of dilute magnetic semiconductors (e.g., GaAsMn, GaNMn, ZnO:Co, ZnO:Mn), magnetic topological insulators (e.g., Cr-doped (Bi,Sb)₂Te₃), AFM with spatial inversion asymmetry (e.g., CuMnAs, Mn₂Au), FM with spatial inversion asymmetry, and topological insulator [e.g., Bi2Se3, Bi2Te3, BSTS (Bi Se, Te, Sb, Cr)/FM bilayers.

In an embodiment the sensor element may comprise FM/NM/Bi trilayers in which FM can be any type of ferromagnet and NM is a non-magnetic metal such as Cu, Ag, Au, carbon, etc.

In an embodiment the sensor element comprises a material with in-plane anisotropy such that the sensor element has an elliptical shape.

The aspect ratio of the elliptic sensor element can be varied accordingly in order to optimize the sensor performance. As will be well understood by the person skilled in the art, the optimum aspect ratio depends on the materials used for the sensing element. In an embodiment the aspect ratio is from 2:1 to 16:1. In an embodiment the aspect ratio is from 4:1 to 12:1. In an embodiment the aspect ratio is from 6:1 to 10:1. In an embodiment the aspect ratio is 8:1.

In an embodiment the sensor element comprises a [Pt/FeMn]ₙ multilayer. A [Pt/FeMn]ₙ multilayer suitable for use in the current invention, is disclosed by us in U.S. patent application Ser. No. 15/438,232, the contents of which are incorporated herein by reference.

The thicknesses of both Pt and FeMn layers in the multilayer structure can be varied within a reasonable range. In this structure, spin current is generated by the Pt layers, and then absorbed by the neighboring FeMn layers to generate SOT and the need to generate SOT governs the dimensions of the layers. In an embodiment the sensor element comprises a [Pt(t₁)/FeMn(t₂)]ₙ multilayer, where t₁ is from 0.4 to 0.8 and t₂ is from 0.2 to 1 nm. In an embodiment the sensor element comprises a [Pt(t₁)/FeMn(t₂)]ₙ multilayer, where t₁ is from 0.2 to 0.6 and t₂ is from 0.4 to 0.8 nm. In an embodiment the sensor element comprises a [Pt(t₁)/FeMn(t₂)]ₙ multilayer, where t₁ is 0.4 and t₂ is 0.6 nm. It will be appreciated that the layer thickness can vary beyond this range as long as the materials are still ferromagnetic with a small coercivity. The number of repeat layers in the multilayer structure can be varied within a reasonable range. In an embodiment n is an integer from 2 to 12. In an embodiment n is an integer from 4 to 10. In an embodiment n is 6.

It will be appreciated that the sensor element materials mentioned herein may be grown on a suitable substrate material, such as silicon or any other type of materials which can support the growth of thin films. In an embodiment the sensor element comprises an oxide layer formed on the Si substrate. The oxide layer provides electrical insulation. It will be appreciated that the substrate itself may already be an insulator. In an embodiment the insulating substrate layer is glass.

In an embodiment the element includes a capping layer to prevent it from oxidation. The thickness of the capping layer may be varied within a reasonable range provided that it can protect the sensor element for long-term stability. In an embodiment the Pt layer is from 0.6 nm to 1.4 nm thick. In an embodiment the capping layer is from 0.8 nm to 1.2 nm thick. In an embodiment the capping layer is 1 nm thick. In an embodiment an additional oxide layer is provided to cover the Pt layer when the thickness of Pt layer is small.

In an embodiment the capping layer comprises a HM. In an embodiment the capping layer comprises a HM material selected from one or more of the group consisting of Pt, Pd, W, Pb, and Nb. In an embodiment the capping layer comprises a Pt layer.

In an embodiment materials with perpendicular or tilted anisotropy are used as the sensor element.

In an embodiment the sensor element comprises a Pt/Co multilayer, Pd/Co multilayer, Ni/Co multilayer, FePt, Co/Pt bilayer, oxide/Co/Pt, oxide/CoFeB/Ta, or oxide/CoFeB/Pt.

The magnetization of [Pt/FeMn]ₙ multilayers can be reversibly switched by the current-induced SOT, with or without an additional Pt layer. The current density for inducing magnetization switching in a standalone multilayer with a total thickness of 5 nm is of the order of 10⁶ A/cm², which is much lower than for other HM/FM bilayers with similar FM thicknesses.

Transparent sensors offer new possibilities for emerging applications in internet-of-things (IOT) and smart living. Although a variety of transparent or semitransparent devices have been demonstrated using semiconductors, polymers, and two-dimensional materials, it remains a great challenge to achieve the same in magnetic devices. This is because most of the practical magnetic materials are metals whose transmissivity in the visible range of electromagnetic spectrum diminishes quickly as the thicknesses increases. For instance, the transmittance of Fe, Co and Ni is only about 20% at a thickness of 10 nm, and it decreases to about 5-6% at 20 nm. As described previously in conventional most magnetic sensors, in addition to the ferromagnetic active layer, one also needs additional layers for magnetic biasing which is essential for sensor linearization. Accordingly the total thickness of conventional magnetic sensor elements can easily exceed 20 nm. This makes it difficult, if not impossible, to realize all-metal-based transparent magnetic sensors using the conventional bias schemes.

The use of SOT effective field for biasing not only simplifies the sensor structure but also makes it possible to make semitransparent sensors.

The concept of SOT biasing applies to various materials including different FM/HM combinations. In an embodiment the sensor is a semi-transparent anisotropic and spin Hall magnetoresistance sensor based on ferromagnet/heavy metal heterostructure.

In an embodiment the sensor is a semi-transparent anisotropic and spin Hall magnetoresistance sensor based on NiFe/HM heterostructure.

In an embodiment the NiFe/HM heterostructure comprises a NiFe(d_{NiFe})/HM(d_{HM}) bilayer where the HM is selected from the group consisting of Pt, Pd, Ta, W, Pb and Nb. Typically the HM is Pt.

In an embodiment d_{HM} is between 1.0 nm and 3.0 nm. In an embodiment d_{HM} is between 1.0 and 3.0 nm. In an embodiment d_{HM} is between 1.5 and 2.0 nm.

In an embodiment d_{NiFe} is between 1.0 nm and 3.0 nm. In an embodiment d_{NiFe} is between 1.0 and 3.0 nm. In an embodiment d_{NiFe} is between 1.5 and 2.0 nm.

In an embodiment the bilayer is formed on a substantially transparent or translucent substrate. In an embodiment the substrate has transparency of >95% In an embodiment the substrate is selected from quartz, or another types of transparent materials (with a transparency >95%). In an embodiment the substrate is quartz.

In an embodiment the NiFe/HM heterostructure comprises a NiFe(d_{NiFe})/HM(d_{Pt})/oxide(d_{oxide}) trilayer. In an embodiment the oxide layer is selected from the group consisting of Ta₂O₅, SiO₂, MgO, and Al₂O₃.

In an embodiment d_{Pt} is between 1.0 nm and 3.0 nm. In an embodiment d_{Pt} is between 1.0 and 3.0 nm. In an embodiment d_{Pt} is between 1.5 and 2.0 nm.

In an embodiment d_{NiFe} is between 1.0 and 3.0 nm. In an embodiment d_{NiFe} is between 1.5 and 2.5 nm. In an embodiment d_{NiFe} is between 1.5 and 2.0 nm.

In an embodiment d_{oxide} is between 1.0 and 3.0 nm. In an embodiment d_{oxide} is between 1.5 and 2.5 nm. In an embodiment d_{oxide} is between 1.5 and 2.0 nm.

Although the SOT biasing scheme in accordance with this invention is best suited for AMR/SMR and PHE sensors, it can also be exploited for biasing applications in giant magnetoresistance (GMR) sensors, spin-valve (SV) sensors, and magnetic tunnel junctions (MTJ) sensors, either partly or fully whenever appropriate.

In an embodiment the sensor element the sensor element functions as both a biasing layer and an active layer in an AMR or PHE sensor. Therefore biasing arrangements of the type described for conventional AMR or PHE sensors are not required in magnetic sensors in accordance with the current invention.

Compared to magnetoresistance resistance sensors, PHE sensors are less sensitive to temperature variation. In the simplest case, a single layer of ferromagnet may form a PHE element.

A PHE sensor measures the Hall signal caused by application of an external magnetic field. A voltage difference (the Hall voltage) is generated transverse to an electric current generated in the sensor by the external magnetic field. Detection of the change in magnetoresistance typically occurs by application of a sensor voltage across terminals in physical connection with the sensor element. The person skilled in the art will appreciate that in some designs contacts for the terminals will cover part of the sensor from the two ends, and only the central portion is active for sensing.

Various means may be used for determining the magnitude of the voltage difference, as will be well understood by the person skilled in the art. For example, a third terminal may be connected to the sensor to provide a voltage proportional to the current being sensed.

An AMR sensor is commonly used in conjunction with at least one further AMR sensor and circuits for detection of the change in anisotropic magnetoresistance. In an embodiment two AMR sensors are oppositely biased by a sensing current. In an embodiment an AMR sensor is used in conjunction further AMR sensors, such as in a Wheatstone bridge arrangement comprising four AMR sensors. When sensor element is used in bridge form, it will reduce DC offset and thermal drift.

Exemplary embodiments relate to the SOT-biased sensors in accordance with this invention are described below. The following description is presented to enable one of ordinary skill in the art to make and use the invention and is provided in the context of a patent application and its requirements. Various modifications to the exemplary embodiments and the generic principles and features described herein will be readily apparent. The exemplary embodiments are mainly described in terms of particular designs and methods provided in particular implementations. However, the designs and methods will operate effectively in other implementations. Phrases such as “exemplary embodiment”, “one embodiment” and “another embodiment” may refer to the same or different embodiments as well as to multiple embodiments. The embodiments will be described with respect to material and device design, synthesis of said material and fabrication of said device, and experimental verification of their functionalities. The exemplary embodiments will also be described in the context of particular methods having certain steps. However, by no means does this exclude other methods having different and/or additional steps and steps in different orders that are not inconsistent with the exemplary embodiments. Thus, the current invention is not intended to be limited to the embodiments shown, but is to be accorded the widest scope consistent with the principles and features described herein.

### EXAMPLES

### Example 1: PHE Sensor

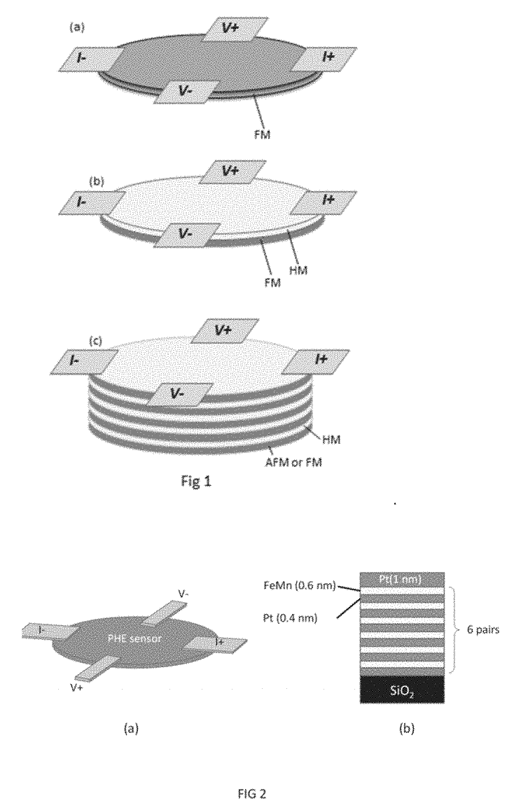

FIG. 1(b) explains the working principle of SOT-biased PHE sensor compared to a convention PHE design without biasing capability. In this specific example, the sensing element is a FM/HM bilayer. Current flows in the sensor between the two electrodes (marked I⁺ and I⁻), and the PHE signal is detected across the two voltage probes (marked V⁺ and V⁻). The current plays a two-fold purpose, i.e., serving as a sense current and at the same time generating a SOT bias field (H_{bias}). The bias field is perpendicular to the current direction. The role of the bias field is also two-fold in the PHE sensor of the current invention. On one hand, it cancels the effect of any undesirable field such as the earth field and makes the sensor's linear range symmetrical with respect to the external field and on the other hand, it helps to stabilize the domain structure. The actual sensor has an elliptic shape. The elongated shape serves to induce moderate shape anisotropy in the current direction. In this specific embodiment, the aspect ratio is 8:1. The sensing element in this example may be a bilayer, as seen in FIG. 1(b), or a multilayer with a structure of SiO₂/[Pt(0.4)/FeMn(0.6)]₆/Pt(1) as seen in FIG. 1(c) and FIG. 2. The multilayer structure comprise an oxide layer formed on the Si substrate (SiO₂) with 6 pairs of Pt and FeMn repeat layers built on top of the oxide layer. The thicknesses of Pt and FeMn as well as the number of repeating layers can be varied within a reasonable range, but in this instance the Pt layers are 0.4 nm thick and the FeMn layers are 0.6 nm thick. The element includes a Pt capping layer which is 1 nm thick. Prior to the deposition of the multilayer, a suitable seed layer, e.g. Ta, may be employed to improve the adhesion and texture of the multilayer. The person skilled in the art will know how to select a proper seed layer.

Spin current is generated in this structure by the Pt layers. The spin current is then absorbed by the neighboring FeMn layer or layers to generate SOT. There are two types of effective fields generated by the SOT. The so-called field-like effective field is in the plane and perpendicular to the current direction. The so-called damping-like effective field is out-of-plane. Considering the relatively large demagnetizing field, the damping-like effective field plays a very minor role in structures with in-plane anisotropy. The field-like effective field can be used to switch the magnetization when there is a misalignment of the easy axis with respect to the current direction. However, as in the current embodiment where the easy axis and current direction are aligned, the field-like effective field will not be able to switch the magnetization; instead, it can function as a bias field to suppress domain wall nucleation and propagation and at the same time to improve the linearity of the sensor.

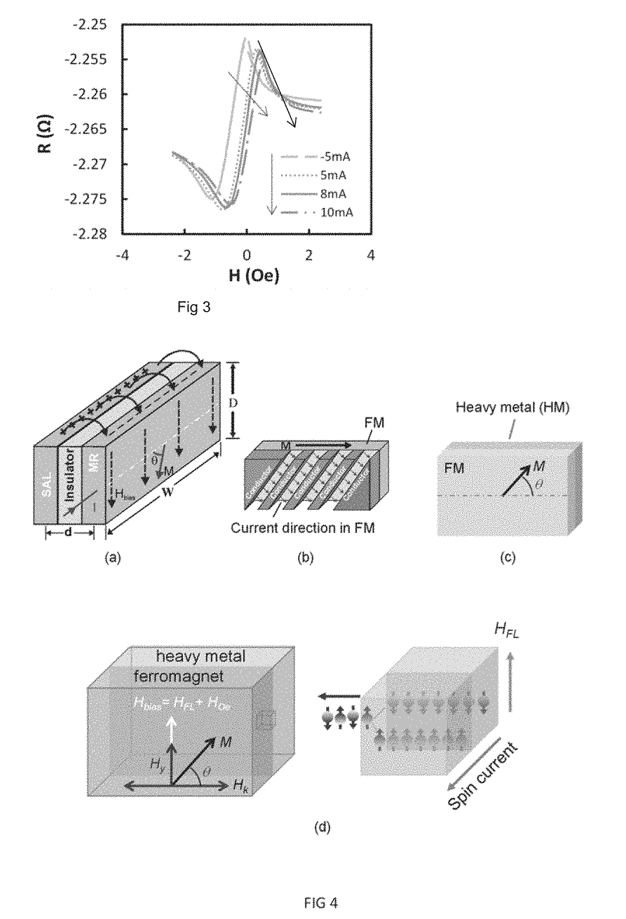

FIG. 3 shows the PHE signal as a function of the external field in the voltage probe direction for the sensor element shown in FIG. 2. When the sense current is varied, the PHE curve shifts along the field direction and changes its shape accordingly. This is because the field-like effective field is dependent on the sense current direction and magnitude. Therefore, the SOT effective field functions as a very effective and built-in bias field.

### Example 2: SOT Generation Mechanism

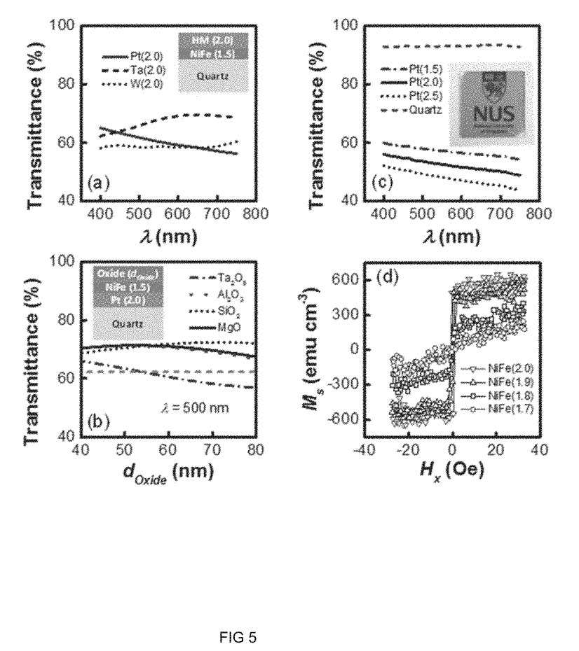

FIG. 4 is a schematic drawing comparing an AMR sensor with soft adjacent layer biasing (FIG. 4(a)) and an AMR sensor with barber pole biasing (FIG. 4(b) with a SMR/AMR sensor with SOT-biasing (FIG. 4(c)). The conventional soft-adjacent layer (SAL) transverse bias scheme shown in FIG. 4(a) comprises a SAL is made of a soft ferromagnetic material. The SAL is formed into a multilayer structure comprising a sensing layer (MR) with a thin insulating spacer separating the SAL and the sensing layer. Most of the current flows through the sensing layer. The magnetic field induced by the sensing current magnetizes and saturates the SAL in one direction (pointing upward in FIG. 4 (a). The fringe field thus generated, in turn, provides a transverse bias to the sensing layer. The bias angle is set by the combined effects of the thickness and magnetization of each of the MR and the SAL, and is fine-tuned by adjusting the current.

In the barber pole biasing arrangement shown in FIG. 4(b) magnetization is fixed in the longitudinal direction by shape anisotropy. Current is directed to be 45° away from the magnetization direction by the conducting strips.

In contrast, in the current invention (as seen in FIG. 4(c)) the sensing elements consists of only an ultrathin bilayer (e.g., NiFe/Pt) or any ferromagnet with the capability to generate SOT effective field (e.g., FeMn/Pt multilayers). There are no additional layers for biasing like the SAL and barber pole scheme.

In the case of FM/HM bilayers (e.g., NiFe/Pt), charge current flowing in the HM layer generates transverse spin current which is partially absorbed by the FM layer, thereby generating the SOT effective field(FIG. 4(d). The SOT effective field functions as an adjustable bias field.

In the case of a single ferromagnet with the capability of generating SOT, the SOT effective field is generated inside the material itself

### Example 3 Semi-Transparent AMR/SMR Sensors

This example describes semitransparent anisotropic and spin Hall magnetoresistance (MR) sensors with a transmittance exceeding 50% in the visible range. The key to achieving semitransparency is the use of spin-orbit torque (SOT) effective field for transverse bias which significantly reduces the total thickness of the sensor, down to 3-4 nm.

The NiFe/Pt bilayers were deposited on quartz substrates with the NiFe layer deposited first by e-beam evaporation and followed by the deposition of Pt using DC magnetron sputtering. Both layers were deposited in a multi-chamber system at a base pressure below 3×10⁻⁸ Torr without breaking the vacuum. An in-plane field of ˜500 Oe was applied during the deposition to induce a uniaxial anisotropy for the magnetic film. Before patterning into sensor elements, thickness optimization was carried out on coupon films by characterizing both the optical transmittance and magnetic properties.

FIG. 5(c) shows the measured transmittance for NiFe(1.5)/Pt(d_{Pt}) films with d_{Pt}=1.5 nm, 2 nm and 2.5 nm, respectively. As a reference, the transmittance of bare quartz substrate is also shown in the figure. The measured transmission spectra are in good agreement with the simulated results shown in FIG. 5(a); and as expected, over 50% transmittance is obtained for the d_{Pt}=2 nm sample in the visible range. As shown in the inset of FIG. 5(c), the semitransparency of the NiFe(1.8)/Pt(2) bilayer is clearly demonstrated in the photograph of NUS logo covered by the coupon film. The magnetic properties of the films were characterized by measuring the M-H loops using a vibrating sample magnetometer with field applied in-plane in the induced anisotropy axis direction. The results are shown in FIG. 5(d) for NiFe(d_{NiFe})/Pt(2) with d_{NiFe}=1.7 nm, 1.8 nm, 1.9 nm, and 2 nm, respectively. Both the d_{NiFe}=1.9 nm and 2 nm samples exhibit typical soft FM behavior with in-plane anisotropy and a coercivity of around 1 Oe, whereas the d_{NiFe}=1.7 nm sample shows a superparamagnetic behavior at room temperature. The behavior of the d_{NiFe}=1.8 nm sample falls between those of d_{NiFe}=1.7 nm and 1.9 nm: it shows a clear magnetization switching but negligibly small coercivity. It is possible that a small portion of the sample becomes superparamagnetic while the remaining part is FM. In view of these results, in order to harness the high transmittance and large SOT effect at small thickness yet not to compromise the FM behavior, we chose to fabricate SOT-biased sensors with a structure of NiFe(1.8)/Pt(2).

The transmittance of FM/HM bilayers can be readily calculated using the transfer matrix method (such bilayers may be made in accordance with Example 2). The inset of FIG. 5(a) shows a typical sensor structure consisting of a HM layer, a NiFe layer and supporting substrate. The thicknesses and refractive indices of the individual layers are dₘ (m=1 for HM and 2 for NiFe), d_{S} and nₘ, n_{S}, respectively. Here, the reflective indices are in general complex numbers. We also assume that dₛ approaches infinity. Assuming that light travels in the zx plane with either s-polarization (\vec{E}∥ŷ) or p-polarization (\vec{H}∥ŷ), the amplitude of the electrical field of a plane wave that satisfies the Maxwell equation can be written as E=[A(x)+B(x)]e^{i(ωt-k}^{_{z}}^{z)}, where k_{z} is the z component of the wave vector, ω is the angular frequency, t is time, and A(x) and B(x) are amplitude of the right-travelling and left-travelling waves, respectively. The amplitude of the electrical field inside the air and those after passing through the m^{th} layer and substrate interface are related by the following equation:

$$( \begin{matrix}{A}_{0} \\ {B}_{0}\end{matrix} ) = {D}_{0}^{- 1} [ {\prod }_{m = 1}^{N} {D}_{m} {P}_{m} {D}_{m}^{- 1} ] {D}_{s} ( \begin{matrix}{A}_{s} \\ {B}_{s}\end{matrix} )$$

$$where$$

$${D}_{m} = ( \begin{matrix}1 & 1 \\ {n}_{m} cos {θ}_{m} & - {n}_{m} cos {θ}_{m}\end{matrix} ) for s \text{-} polarization$$

$${D}_{m} = ( \begin{matrix}cos {θ}_{m} & cos {θ}_{m} \\ {n}_{m} & - {n}_{m}\end{matrix} ) for p \text{-} polarization$$

and

$${P}_{m} ( \begin{matrix}{e}^{i {ω}_{m}} & 0 \\ 0 & {e}^{- i {ω}_{m}}\end{matrix} )$$

is the propagation matrix,

$${ω}_{m} = \frac{2 π {n}_{m} {d}_{m} cos {θ}_{m}}{λ}$$

is the change in phase after the light passing through the m^{th} layer. Here, λ is the wavelength, and θₘ is angle of incidence in the m^{th} layer. If we let

$${D}_{0}^{- 1} [ {\prod }_{m = 1}^{N} {D}_{m} {P}_{m} {D}_{m}^{- 1} ] {D}_{s} = ( \begin{matrix}{M}_{11} & {M}_{12} \\ {M}_{21} & {M}_{22}\end{matrix} ) ,$$

then the transmittance is given by

$$T = \frac{{n}_{s} cos {θ}_{s}}{{n}_{0} cos {θ}_{0}} {⌊ \frac{1}{{M}_{11}} ⌋}^{2} .$$

For unpolarized light, one can take an average of the contributions from both the s-polarization and p-polarization light. FIG. 5(a) shows the simulated transmittance (θₘ=0) in the visible range for NiFe(1.5)/HM(2) bilayers on quartz substrate with different HMs, i.e., Pt, Ta and W (number in the parenthesis indicates thickness in nanometer). It is clearly seen that all the bilayers exhibit a transmittance over 50%. The different trend of the curves for different HMs is due to the different dispersion of refractive indices. The transmittance can be further enhanced by adding an oxide capping layer that functions as an anti-reflection coating. FIG. 5(b) shows the simulated oxide thickness dependence of transmittance for Pt(2)/NiFe(1.5)/oxide(d_{oxide}) trilayers (see inset of FIG. 5(b)) with different oxides Ta₂O₅, SiO₂, MgO and Al₂O₃ at λ=500 nm. As a reference, the transmittance of Pt(2)/NiFe(1.5) bilayer is also shown in dashed line. With the oxide anti-reflection coating, it is possible to achieve a transmittance up to 70% capped by SiO₂, MgO and Al₂O₃ layers. It should be noted that, in addition to enhancement of transmittance, the oxide capping layer may also help to strengthen the SOT effect.

### Example 4: Simulated Sensor Response

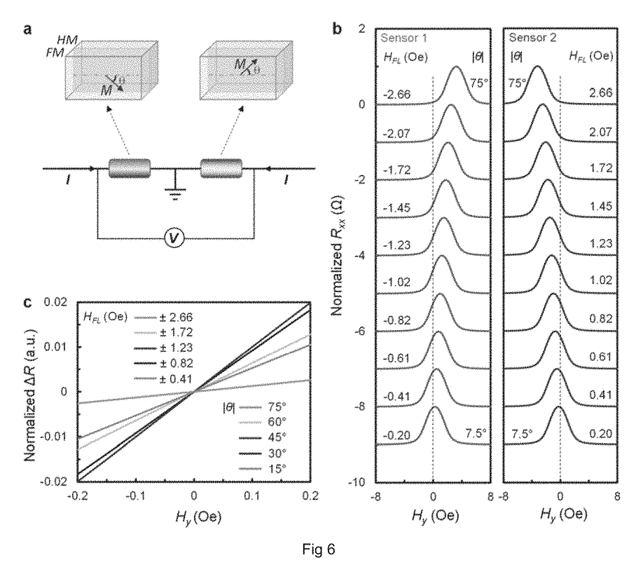

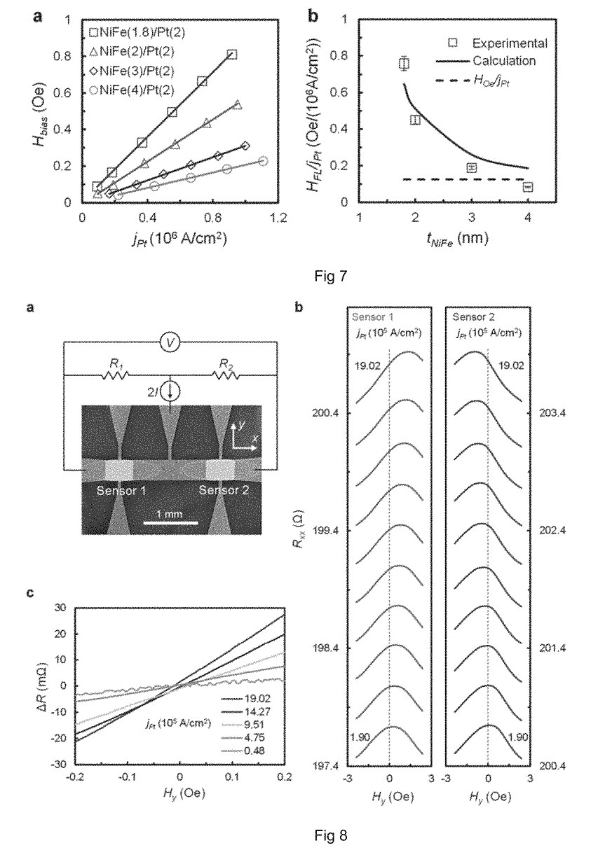

The SOT biasing is ideal for differential sensing using two AMR sensors (as discussed above, the MR in ultrathin FM/HM bilayers contains both AMR and SMR, but for simplicity we simply call it AMR). The bilayers used here may be made in accordance with Example 2. As shown schematically in FIG. 6a, when the two sensors are oppositely biased by the sensing current, the SOT effective field rotates the magnetization of the two sensors in opposite directions off the easy axis by an angle θ. A linear response with maximum sensitivity is obtained when both magnetizations are 45° away from the easy axis. Although similar magnetic configuration can also be realized using the conventional barber-pole structure, the SOT biasing is much simpler as it does not require patterned metallic strip to direct the sensing current to be 45° from the sensor element's easy axis. This greatly simplifies the fabrication processes for AMR sensors. By assuming H_{d}+Hₖ=1.9 Oe, the sensor's response under the biasing of different H_{FL} can be simulated using the energy minimization method. The simulated AMR curves are shown in FIG. 6b (left panel for sensor 1 and right panel for sensor 2) which correspond to θ=−7.5° to −75° for sensor 1 and θ=7.5° to 75° for sensor 2 with a step size of 7.5°. The corresponding H_{FL} values required are also given in the figure, i.e., −0.2 Oe to −2.66 Oe for sensor 1 and 0.2 Oe to 2.66 Oe for sensor 2. The opposite sign of H_{FL} is a direct result of different current direction in the two sensors. To bias the magnetization into 45° from the easy axis, one only needs a SOT effective field of 1.23 Oe which, as we will discuss shortly in the experimental part, can be readily obtained in NiFe/Pt bilayers with a thin NiFe layer. It is worth noting that at this condition both sensors exhibit maximum sensitivity but they are operating in the different quadrant of the magnetization with respect to the easy axis, which is the key to obtaining linear and symmetrical response from the oppositely biased sensor pair. FIG. 7c shows the calculated magnetoresistance as a function of external field H, at different SOT bias field, i.e., H_{FL}=±2.66, ±1.72, ±1.23, ±0.82, and ±0.41 Oe. At these H_{FL} values, the corresponding θ values are |θ|=75°, 60°, 45°, 30°, and 15°, respectively. The Oersted field generated by the current was included in the calculation. As can be seen from the figure, a linear response with maximum sensitivity is obtained at H_{FL}=1.23 Oe, and the sensitivity decreases with either increasing or decreasing the H_{FL} from this value. It is important to note that the linear response is obtained in a very simple bilayer structure without any additional magnetic bias except for the SOT effective field.

### Example 5: FL Effective Field in NiFe/Pt Bilayers

In order to quantify the H_{FL}/j_{Pt} ratio experimentally, we measured the H_{bias}, which is the sum of H_{FL} and H_{Oe} in y-direction, as a function of current density for NiFe(t_{NiFe})/Pt(2) bilayer structures with t_{NiFe}=1.8, 2, 3 and 4 nm by using the 2^{nd} order planar Hall effect (PHE) method. The devices used for extracting H_{bias} were fabricated directly on SiO₂/Si substrates without any seed layer using combined technique of sputtering/evaporation and lift-off. The devices were ellipsoid shaped with a long axis of 3000 μm and short axis of 375 μm while an easy axis is induced in the long axis (or x-) direction by applying an external in-plane magnetic field during deposition. As summarized in FIG. 7a, the H_{bias} values extracted directly from experiments scale linearly with the current density in Pt layer at different NiFe thickness. The ratio H_{FL}/j_{Pt} is obtained and shown in FIG. 7b as a function of the NiFe layer thickness after subtracting the contribution from the Oersted field in the bilayers. For NiFe(t_{NiFe})/Pt(t_{Pt}) bilayer with a lateral dimension of a×b, where a (b) is the long axis length (short axis length) of the sensor element, the Oersted field in the middle of NiFe layer due to current in the Pt layer is given by

$$\frac{{H}_{O e}}{{j}_{Pt }} = \frac{{t}_{Pt}}{2}$$

when b>>t_{Pt}, t_{NiFe}. In the present case, t_{Pt}=2 nm, therefore H_{Oe}/j_{Pt}=0.126 Oe/(10⁶ A/cm²). The estimated H_{Oe}/j_{Pt} ratio is shown in FIG. 7b in dotted-line, which alone is apparently too small to account for the experimentally observed biasing field (H_{bias}) in y-direction and also the NiFe thickness dependence of H_{bias}/j_{Pt}. SOT is dependent on the spin mixing conductance at the interface, which varies from sample to sample. It is, therefore, more meaningful to focus on the NiFe thickness dependence rather than absolute values of H_{FL}/j_{Pt}. As such, we may express the SOT efficiency as

$$\frac{{H}_{FL}}{{j}_{Pt}} = \frac{ℏ}{2 e} \frac{{θ}_{SH} α}{{μ}_{0} {M}_{s} {t}_{NiFe}} ,$$

where α is a parameter that contains spin mixing conductance at NiFe/Pt interface, thickness and spin diffusion length of Pt but is independent of NiFe thickness, t_{NiFe}. θ_{SH}α is equivalent to the effective spin Hall angle. As the saturation magnetization at small thickness is usually different from its bulk value, we measured the saturation magnetization of NiFe(t_{NiFe})/Pt(2) bilayers at different NiFe thicknesses using a vibrating sample magnetometer, and the Mₛ values obtained are μ₀Mₛ=0.65, 0.74, 0.97 and 1.02 T for t_{NiFe}, =1.8, 2, 3 and 4 nm, respectively. Using these values, the experimental data shown in FIG. 8b can be fitted reasonably well by assuming θ_{SH}=0.15 and α=0.122 (note H_{FL}=H_{bias}−H_{Oe}). These results confirm that the main contribution of the experimentally observed biasing effective field is from the SOT effective field. In addition to its much larger strength as compared to H_{Oe}, the H_{FL} is also more uniform in samples with a finite size, especially at the edge of the samples.

### Example 6: Linearization by SOT Effective Field

To verify the SOT-biasing effect and compare it with the simulation results shown in FIG. 7, we fabricated two ellipsoid shaped NiFe(2)/Pt(2) sensors with a long axis length of 1500 μm and an aspect ratio of 4:1. As shown in the scanning electron micrograph (SEM) in FIG. 8a, the two sensors are connected at the middle and form a Wheatstone bridge with two external resistors R₁ and R₂. The values of R₁ and R₂ are adjusted slightly to account for the process induced small difference in the resistance of the two sensors. When a current source is connected to the bridge as depicted in the FIG. 8a, the magnetization of the two sensors are rotated to opposite directions with respect to the easy axis, leading to a linear response to the external field which is detected as a voltage signal from the other two terminals of the bridge. FIG. 8b shows the MR curves of both sensors (left panel: sensor 1 and right panel: sensor 2) at bias current densities ranging from 1.9×10⁵ A/cm² to 1.9×10⁶ A/cm². When the bias current increases, the curves are shifted in opposite directions. A nearly linear region with maximum sensitivity is obtained for both sensors near H_{y}=0 when the current density is around 1.9×10⁶ A/cm². As with the simulated curves in FIG. 7b, the two sensors are operating in the different quadrant of the magnetization with respect to the easy axis, leading to linear and symmetrical responses when connected in a bridge in FIG. 8a. Shown in FIG. 8c are the output signals as a function of H_{y} at different bias current densities. The output signal ΔR is defined as the output bridge voltage divided by the current passing through the bilayer sensor element. The sensor exhibits good linearity with a maximum sensitivity at j_{Pt}=1.9×10⁶ A/cm², which decreases by increasing or reducing the bias current. This is in good agreement with the simulation results shown in FIG. 7c. The results demonstrate clearly good tunability of SOT-biasing.

### Example 7: SOT-Biased Wheatstone Bridge Sensors

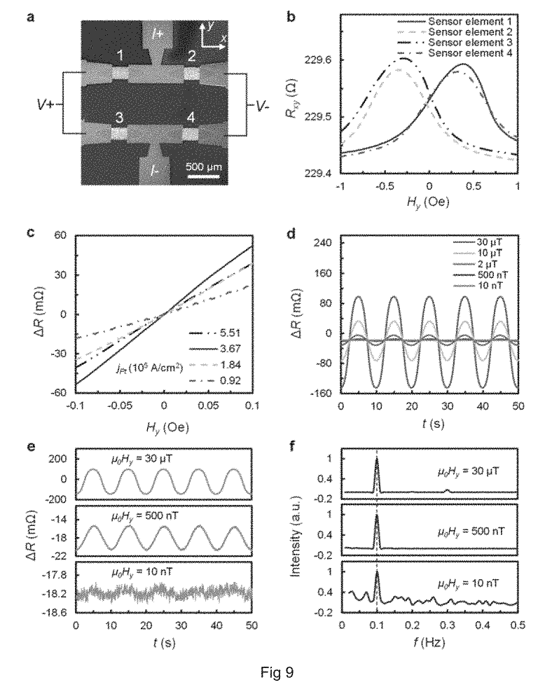

In order to evaluate the field sensing performance of SOT biased sensors with different dimensions, we fabricated full Wheatstone bridge sensors with ellipsoidal shape in NiFe(1.8)/Pt(2) bilayers. The long to short axis ratio is fixed at a/b=4, with a=800, 400 and 200 μm, respectively. The distance (L) between the two electrical contacts for each sensor element is kept a/3. In order to minimize the influence of earth field, both the sensors and Helmholtz coils for generating the field were placed inside a magnetically shielded cylinder made of 7 layers of μ-metals. FIG. 9a shows the scanning electron micrograph of the four sensor elements with a=800 μm, which are connected to form a Wheatstone full bridge. When a current source is connected to the top and bottom terminals of the bridge sensor as depicted in the FIG. 9a, the magnetization of the sensor elements, 1 and 4, are rotated to the direction opposite to that of the sensor elements, 2 and 3, with respect to the easy axis, leading to a linear response to the external field which is detected as a voltage signal from the other two terminals of the bridge. FIG. 9b shows the AMR curves of all the four sensor elements at the same bias current densities of 3.67×10⁵ A/cm² at which a nearly linear response region with maximum sensitivity is achieved at zero external field. Shown in FIG. 9c are the output signals as a function of H_{y} at different bias current densities. The sensor exhibits good linearity with a maximum sensitivity at j_{Pt}=3.67×10⁵ A/cm², which decreases by increasing or reducing the bias current. From the slope of the response curve in FIG. 8c, we can extract the maximum sensitivity of the sensor which is 0.548 Ω/Oe.

In order to examine the detection limit of these SOT-biased full bridge AMR sensors, we performed AC field sensing experiments and analyzed the waveform of the output signal. During these experiments, an AC magnetic field with various magnitudes and fixed frequency of 0.1 Hz was applied in y-direction, while the sensor output was recorded with respective to time. The output signals of the sensor with a=800 μm, when being biased at a current density of j_{Pt}=3.67×10⁵ A/cm² and used to detect a 0.1 Hz AC field with amplitudes ranging from 10 nT to 30 μT are summarized in FIG. 9d. The amplitude of output signal decreases with the amplitude of applied AC external field, and is eventually masked out by the noise. To have a clearer view of the background noise, we re-display the output signals obtained at AC field amplitudes of 30 μT. 500 nT and 10 nT in FIG. 9e. The corresponding Fourier transform (FT) of the output waveforms is shown in FIG. 9f. As can be seen, a clear peak at 0.1 Hz can be identified for all three cases. However, as the amplitude of the applied AC field decreases further to below 10 nT, the 0.1 Hz peak becomes indistinguishable (not shown here). Therefore, the resolution of the sensor with a=800 μm is around 10 nT.

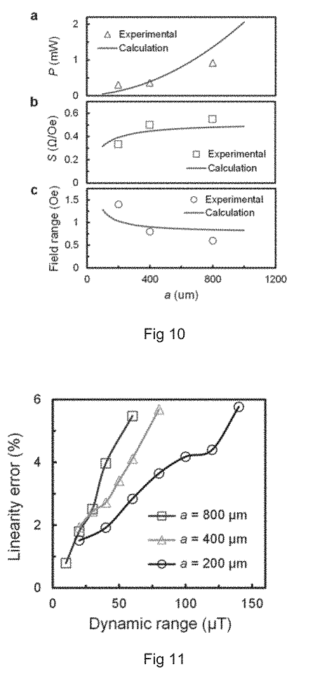

Similar measurements were performed on the other two sensors with a=400 and 200 μm, respectively. The bias current densities required to achieve linear response with maximum sensitivity at zero external field are 4.59×10⁵ A cm⁻² and 8.44×10⁵ A cm⁻², for a=400 and 200 μm, respectively. In AC field sensing measurements, the resolution of the two sensors turned out to be 20 and 70 nT, for the sensors with a=400 and 200 μm, respectively. In FIG. 10, we show the sensor size dependence of power consumption, sensitivity, and dynamic range of the three sensors (symbols). By changing the long and short axis length (a and b), the shape anisotropy of the sensor can be changed accordingly; this leads to tunable bias current density, power consumption, sensitivity and dynamic range. The solid curves in FIG. 10 are calculated based on the formulas derived in previous section, using the L/a=1/3, a/b=4, ρ_{pT}=31.66 μΩ·cm, ρ_{NiFe}=78.77 μΩ·cm, μ₀M_{S}=0.65 T, Δρ_{NiFe}/ρ_{NiFe}=0.06%, Hₖ=0.5 Oe, t_{NiFe}=1.8 nm and t_{Pt}=2 nm. From the calculation results, we can observe, by reducing a from 1000 μm to 100 μm, the power consumption decreases significantly from 2.06 mW to 0.05 mW, the sensitivity decreases from 243.2 to 157.0 mΩ/Oe and the dynamic range increases from 0.83 to 1.28 Oe. These changes are attributed to the increased shape anisotropy and reduced current as the dimension decreases. The agreement between experimental and simulated results shows clearly that it is possible to tune the sensor's power consumption, sensitivity and dynamic range via adjusting the dimensions.

All the sensors exhibit good linearity at low field, but the linearity error increases with the applied field. FIG. 11 shows the experimentally extracted linearity error as a function of the dynamic range. Here, the linearity error (%) is defined as the deviation of the sensor output curve from a specified straight line over a desired dynamic range. It is clearly shown that the linearity error increases as the dynamic range increases, which is typical for AMR sensors. Compared to commercial AMR sensors, the dynamic range of SOT-biased NiFe/Pt bridge sensor is small, mainly because of the relatively small H_{FL} (˜1 Oe) in this specific material system. Hence, in order to have good linearity, the external field must be smaller than the transverse biasing field which in this case is the sum of H_{FL} and H_{Oe}. By defining the working field range as the dynamic range that gives a linearity error below 6%, the field ranges for the three sensors are obtained and found to correlate well with calculated values, as shown in FIG. 10c. It is important to note that the sensitivity is inversely proportional to the dynamic field range; the dimension of the sensor has to be optimized in order to achieve desired performance.

### Example 8: On-Chip Current Detection Using SOT-Biased AMR Sensor

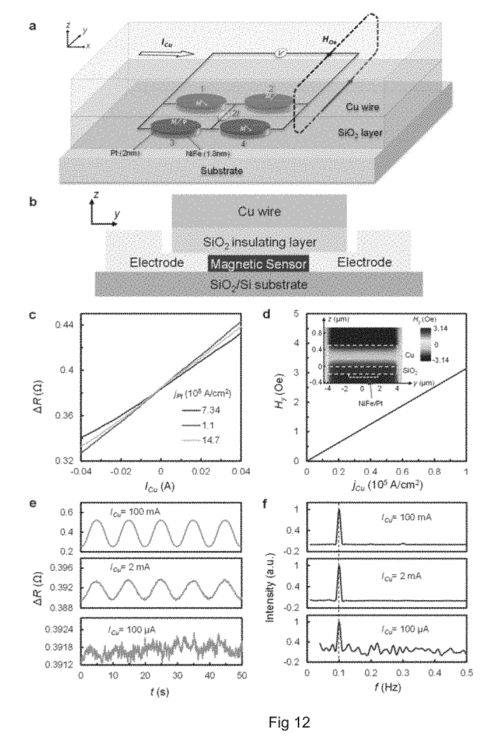

Given its simple structure and ultrathin thickness, SOT-biased sensors can be potentially used in on-chip monitoring of electric current. As a proof-of-concept experiment, we fabricated a Wheatstone bridge sensor with four ellipsoidal shape sensing elements comprised of NiFe(1.8)/Pt(2) bilayers; the entire sensor is then covered with a 200 nm SiO₂ isolation layer, followed by a copper layer with thickness (width) of 500 nm (2000 μm), as shown schematically in FIGS. 12a and b. The dimensions of the sensing elements are kept the same as those shown in FIG. 11a. Current sensing measurements were carried out in a magnetically shielded cylinder with 7 layers of μ-metal sheets. We first established the linear operation region of the sensor by subjecting the sensor to the stray field generated by the current in the copper wire. Shown in FIG. 12c are the bridge output signals as a function of current in the copper wire at different bias current densities in the Pt layer of the sensor elements. The sensor exhibits good linearity with a maximum sensitivity of 1.54 Ω/A at j_{Pt}=1.1×10⁶ A/cm²; the sensitivity decreases with either the increase or decrease of the bias current. The current density required to achieve maximum sensitivity is slightly higher than that for the sensor with the same structure shown in FIG. 11a. This is may be caused by the overlaid SiO₂ layer on the sensor elements; further study is required to optimize the deposition processes.

In order to correlate the current generated stray field with external field, we performed field sweeping measurement on the same sensor using Helmholtz coils, and a maximum sensitivity of 487.2 mΩ/Oe is obtained. This gives a field to current ratio of 3.16 Oe/A, corresponding to a field to current density ratio of 3.16 Oe/(10⁵ A/cm²), for the copper wire at the sensor plane. To compare with the measurement results, we calculated the Oersted field generated by the copper wire using three-dimensional finite element analysis. In order to shorten the calculation time, the dimension of the copper wire was scaled down to 8 μm with the thickness unchanged. The current densities used for the calculation were kept the same as those of the actual device when a current of 0-1 A flows in the copper wire. FIG. 12d shows the calculated Oersted field (H_{y}) at the sensor plane as a function of the current density in the Cu layer (inset shows the distribution of y-component of the Oersted field in yz plane at j_{Cu}=1×10⁵ A/cm²). The slope of the curve is 3.141 Oe/(10⁵ A/cm²), which is close to the experimentally extract value of 3.16 Oe/(10⁵ A/cm²). By defining the working range as the dynamic range that gives a linearity error below 6%, the working current range for the this sensor is about 0.3 A. Similar AC field sensing experiments have been performed, in order to obtain the detection limit of the sensor. To this end, an AC current with varying magnitude but fixed frequency of 0.1 Hz was applied to the Cu wire, and the output of the sensor was recorded for a certain period of time. This sensor was biased at a current density of j_{Pt}=1.1×10⁶ A/cm². The output signals for current with amplitude of 100 mA, 2 mA and 100 μA are shown in FIG. 12e, respectively. The corresponding Fourier transforms of the output waveforms are shown in FIG. 12f. A peak at 0.1 Hz can be clearly identified for all the three current amplitudes. However, as the amplitude of the AC current decreases further to below 100 μA, the 0.1 Hz peak becomes hardly observable (not shown here). Therefore, the current detection resolution of this specific sensor is around 100 μA.

At least in embodiments, the magnetic sensor has significantly simplified design in magnetic sensors by eliminating the need for a conventional bias scheme while providing tuneable response and high linearity and sensitivity. Both longitudinal and transverse biases are realized using the SOT generated effective field. This eliminates the requirement of complex biasing structure and at the same time improves the uniformity of biasing field and sensitivity of the sensor. The magnetic sensor is especially useful for detection of low-magnetic field, e.g., in bio-sensing.

What is claimed is:

1. A magnetic sensor comprising at least one sensor element with an easy axis and a hard axis which is able to generate a spin-orbit torque (SOT) when a charge current passes through it, and electrodes disposed along the easy axis to carry a sense current, wherein the charge current also generates a SOT effective field, thereby providing a transverse bias.

2. The magnetic sensor of claim 1, further comprising electrodes disposed along the hard axis to provide a longitudinal bias.

3. The magnetic sensor of claim 1, wherein the magnetic sensor is selected from the group consisting of anisotropic magnetoresistance (AMR) sensors, spin Hall magnetoresistance sensor and planar Hall effect (PHE) sensors.

4. The magnetic sensor of claim 1, wherein the sensor element is configured to function as both a biasing layer and an active layer in an AMR sensor, a SMR sensor, an AMR/SMR or a PHE sensor.

5. The magnetic sensor of claim 1, wherein the sensor element is in the form of a single layer of material, a heterostructure, or multilayers.

6. The magnetic sensor of claim 5, wherein the single layer of material is selected from the group consisting of a ferromagnet (FM) with a large SOT effect, an anti-ferromagnet (AFM) with large SOT effect, and a magnetic topological insulator.

7. The magnetic sensor of claim 5, wherein the heterostructure is selected from the group consisting of a FM/HM bilayer, an AFM/HM bilayer, a FM/AFM/HM trilayer, an AFM/HM/FM trilayer, an AFM/FM/HM trilayer, and a HM/AFM/FM trilayer.

8. The magnetic sensor of claim 5, wherein the multilayer comprises ultrathin layers of FM and HM or ultrathin layers of AFM and HM.

9. The magnetic sensor of claim 5, comprising an AFM material selected from one or more of the group consisting of FeMn, IrMn, NiFe, PtMn, NiMn, PtNiMn, Mn, Cr, NiO, CoO and CuMnAs.

10. The magnetic sensor of claim 5, comprising a FM material selected from one or more of the group consisting of Co, Fe, Ni, CoFeB and Gd, and alloys comprising Co, Fe, Ni, CoFeB or Gd.

11. The magnetic sensor of claim 5, comprising a HM material selected from one or more of the group consisting of Pt, Pd, Ta, W, Pb, Nb, topological insulators, transition metal dichalcogenide (TMD) and Weyl metal or semimetals.

12. The magnetic sensor of claim 8, wherein the sensor element comprises a [Pt/FeMn]ₙ multilayer where n is an integer from 2 to 12.

13. The magnetic sensor of claim 12, wherein the sensor element comprises a [Pt(t₁)/FeMn(t₂)]ₙ multilayer, where t₁ is from 0.2 to 0.8 nm and t₂ is from 0.2 to 1 nm.

14. The magnetic sensor of claim 5 wherein the sensor element comprises a Pt/Co multilayer, Pd/Co multilayer, Ni/Co multilayer, FePt, Co/Pt bilayer, oxide/Co/Pt, oxide/CoFeB/Ta, oxide/CoFeB/Pt.

15. The magnetic sensor of claim 5 wherein the sensor element comprises a NiFe(d_{NiFe})/HM(d_{HM}) bilayer, where d_{NiFe} is between 1.0 and 3.0 nm, the HM is selected from the group consisting of Pt, Pd, Ta, W, Pb and Nb, and d_{HM} is between 1.0 nm and 3.0 nm.

16. The magnetic sensor of claim 5 wherein the sensor element comprises a NiFe(d_{NiFe})/HM(d_{HM})/oxide(d_{oxide}) trilayer, where d_{NiFe} is between 1.0 and 3.0 nm, the HM is selected from the group consisting of Pt, Pd, Ta, W, Pb and Nb, d_{HM} is between 1.0 nm and 3.0 nm, the oxide layer is selected from the group consisting of Ta₂Os, SiO₂, MgO, and Al₂O₃ and d_{oxide} is between 1.0 and 3.0 nm.

17. The magnetic sensor of claim 1 which is semi-transparent.

18. A magnetic sensor consisting essentially of a sensor element which is able to generate a spin-orbit torque (SOT).

19. A method of measuring a change in a magnetic field, comprising providing a sensor element which is able to generate a spin-orbit torque (SOT) and using said sensor element both to provide transverse bias and, optionally, longitudinal bias and to sense the change in the magnetic field.
